(19) United States
(12) Patent Application Publication
(10) Pub. No.: US 2026/0080959 A1
(43) Pub. Date: Mar. 19, 2026

(54) PROVIDING FLEXIBILITY IN SELECTING DESIRED POWER SUPPLY FOR INTEGRATED CIRCUITS (IC) BASED ON ONE TIME PROGRAMMABLE (OTP) MEMORY

(71) Applicant: Shaoxing Yuanfang Semiconductor Co., Ltd., Shaoxing (CN)

(72) Inventors: Rakesh Kumar Gupta, Bangalore (IN); Raja Prabhu J, Bangalore (IN)

(21) Appl. No.: 19/190,858

(22) Filed: Apr. 28, 2025

(30) Foreign Application Priority Data
Sep. 18, 2024 (IN) 202441070587

(51) Int. Cl. G11C 17/16; H03K 3/037; H03K 19/21; H03L 7/08

(52) U.S. Cl. CPC G11C 17/16; H03K 3/037; H03L 7/08; H03K 19/21

(57) ABSTRACT

An integrated circuit (IC) containing a circuit to be operable using one of multiple unequal power supplies during normal operation of the IC. The IC contains a one time programmable (OTP) memory containing a first bit and a second bit, with each of the bit having an initial value and being programmable to a programmed value. A configuration engine contained in the IC operates the circuit with a first selection with respect to using one of the unequal power supplies during normal operation of the IC if both of the first bit and the second bit have an equal value comprising one of the initial value and the programmed value. The configuration engine operates the circuit with a second selection with respect to using one of the unequal power supplies during normal operation of the IC if the first bit and the second bit have unequal values.

### PRIORITY CLAIM

The instant patent application is related to and claims priority from the co-pending provisional India patent application entitled, “Multiple Supply-Voltage Pad-Ring System”, Serial No.: 202441070587, Filed: 18 Sep. 2024, which is incorporated in its entirety herewith to the extent not inconsistent with the description herein.

### BACKGROUND

### Technical Field

Embodiments of the present disclosure relate generally to integrated circuits (IC) that use multiple power supply voltages, and more specifically to providing flexibility in selecting desired power supply for integrated circuits (ICs) based on one time programmable (OTP) memory.

### Related Art

Power supply refers to a component or device which generates a stable (regulated) output voltage at an output terminal from an input voltage received at an input terminal, as is well known in the relevant arts. In general, the output voltage is sought to be maintained at a fixed level irrespective of the magnitude of load current that may be drawn by a load powered by the output voltage, or of changes in the magnitude of the input voltage.

An integrated circuit (IC) (including portions thereof) is often designed to operate using a corresponding one of multiple power supplies of different magnitudes. For example, the IC may be able to operate based on both 3.3V and 1.8V, and it may be desirable to specify one of the two voltages based on which the IC is to operate. In another scenario, some portions of the IC may be designed to operate using 3.3V and other portions may be designed to operate using only 1.8V, and it may be necessary to specify the specific voltage using which each portion operates. An IC or a portion thereof is hereafter referred to as a circuit.

One time programmable (OTP) memories are often used to specify the specific voltages, based on which respective circuits are to operate. An OTP memory is a type of non-volatile memory in which each bit is initially at a default (unprogrammed/initial) value (e.g., logic “0”), and can be programmed/changed to another logic value (e.g., logic “1”) only once, but not the other way round thereafter. An example of OTP memory is flash memory, where the single change can be performed in-circuit, and any reversal requires significantly more effort and thus may be deemed impractical in normal industry practices.

Thus, by either leaving at default value or changing to the another value according to pre-specified conventions, the bits may indicate the respective desired voltages to select voltages to drive respective circuits. It should be appreciated that even for a specific circuit, depending on the specific application requirements, some users may want to specify a particular power supply (e.g., 3.3V) while others may want to specify a different power supply (e.g., 1.8V) for powering their respective instances of circuits. Thus, one set of users (for corresponding instances of circuits) may set the corresponding voltage determining bits to one value(s) while the other users may set to another value(s) to select the corresponding desired voltage.

The inventors have noticed a general need to have flexibility in such selection of desired voltage, i.e., a circuit may first be configured for operation with a specific voltage by programming at least one corresponding bit to the above noted another logic value, but then a requirement is recognized to operate that circuit with another voltage. For example, a manufacturer may have programmed an OTP bit to setup the circuit to operate with one voltage value, but a user subsequently may wish to operate the same circuit portion with another voltage value (corresponding to the pre-programmed value). Due to the OTP memory having the characteristic of being programmable only once, it may not be possible to have the flexibility to implement the changed requirement.

Aspects of the present disclosure are directed to providing such flexibility in selecting desired power supply.

### BRIEF DESCRIPTION OF THE VIEWS OF DRAWINGS

Example embodiments of the present disclosure will be described with reference to the accompanying drawings briefly described below.

FIG. 1 is a block diagram of an example device in which several aspects of the present disclosure can be implemented.

FIG. 2A illustrates example logic values of bits in a one time programmable (OTP) memory for selecting power supply voltages for a circuit, in an embodiment of the present disclosure.

FIG. 2B illustrates example logic values of bits in the OTP memory for specifying a mode of configuration of the power supply for the circuit, in an embodiment of the present disclosure.

FIGS. 3A and 3B are diagrams illustrating implementation details of a configuration engine in an embodiment of the present disclosure.

FIG. 4 is a flow-chart illustrating the manner in a configuration engine operates to select desired power supply for ICs based on OTP memory is provided, in an embodiment of the present disclosure.

FIG. 5A is a timing diagram (not to scale) illustrating example values of various signals during reset and until the start of normal operation of IC 100, when a manufacturer of the IC has specified the specific power supply, in an embodiment of the present disclosure.

FIG. 5B is a timing diagram (not to scale) illustrating example values of various signals during reset and until the start of normal operation of IC 100, when a user of the IC specifies the specific power supply, in an embodiment of the present disclosure.

FIG. 6 is a block diagram illustrating the implementation details of a system incorporating an IC implemented according to several aspects of the present disclosure.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

### 1. Overview

Aspects of the present disclosure provide an integrated circuit (IC) containing a circuit to be operable using one of multiple unequal power supplies during normal operation of the IC. The IC contains a one time programmable (OTP) memory containing a first bit and a second bit, with each of the first bit and the second bit having an initial value and being programmable to a programmed value. A configuration engine contained in the IC operates the circuit with a first selection with respect to using one of the unequal power supplies during normal operation of the IC if both of the first bit and the second bit have an equal value comprising one of the initial value and the programmed value. The configuration engine operates the circuit with a second selection with respect to using one of the unequal power supplies during normal operation of the IC if the first bit and the second bit have unequal values.

In an embodiment, the configuration engine contains an XOR gate for performing an XOR operation of the first bit and the second bit to determine the first selection or the second selection.

It may be appreciated that usage of two bits for selection of desired power supply provides the flexibility to switch between the first selection and the second selection up to two time (e.g., first selection to second selection, and then back to first selection).

According to an aspect, both of the first bit and the second bit have the initial value at a first time instance, and only the first bit is programmed to the programmed value at a second time instance following the first time instance to change from the first selection to the second selection. The second bit is then programmed to the programmed value at a third time instance following the second time instance to revert back to the first selection.

According to another aspect, the first selection corresponds to using a first power supply and the second selection corresponds to using a second power supply, the first power supply and the second power supply being contained in the unequal power supplies. The circuit is operated using the first power supply when both of the first bit and the second bit have equal value, and is operated using the second power supply when both of the first bit and the second bit have unequal values.

In an embodiment, only a manufacturer of the integrated circuit is provided ability to program the first and second bits. The manufacturer programs the first bit to the programmed value to indicate the second selection at the second time instance and then programs the second bit at the third time instance to the programmed value to indicate the first selection.

According to another aspect, the OTP memory further contains a third bit and a fourth bit, wherein a manufacturer specifies the selection in the first bit and the second bit when both the third bit and the fourth bit have unequal values, and a user is provided an option to specify whether to use the first power supply or the second power supply when the third bit and the fourth bit have equal value.

Several aspects of the present disclosure are described below with reference to examples for illustration. However, one skilled in the relevant art will recognize that the disclosure can be practiced without one or more of the specific details or with other methods, components, materials and so forth. In other instances, well-known structures, materials, or operations are not shown in detail to avoid obscuring the features of the disclosure. Furthermore, the features/aspects described can be practiced in various combinations, though only some of the combinations are described herein for conciseness.

### 2. Example Device

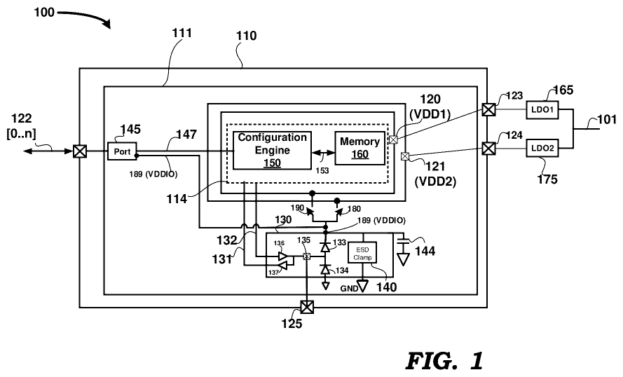

FIG. 1 is a diagram of an example integrated circuit (IC) 100 in which several aspects of the present disclosure can be implemented. Numeral 110 represents the chip package boundary, and numeral 111 represents the chip silicon die boundary. Numeral 114 represents the core area containing electronics circuitry within the silicon die. Pins 122 [0 . . . n] (n being a natural number), 123, 124 and 125 of IC 100 are shown at package boundary 110 in FIG. 1. Although not shown, IC 100 would typically contain many more package pins connected to corresponding die pads.

Core area 114 of IC 100 is shown containing configuration engine 150 and memory 160. Though not shown in FIG. 1, IC 100 contains one or more phase-locked loops (PLLs) and configurable volatile registers in core area 114. Various configuration values needed for configuration of the one or more PLLs are provided by an external device to IC 100 via the I/O ports (or specifically input ports). Some examples of the inputs to the I/O ports are reset input for resetting IC 100, register values for configuring the one or more PLLs (such as feedback divider division factor and pre-scaler values), DCO (digitally controlled oscillator of a PLL) frequency change triggers, general purpose inputs, etc. Some examples of the outputs from the I/O ports are PLL lock/loss-of-lock indications, clock outputs for monitoring by an external device, etc. Thus, the respective inputs (outputs) of the I/O ports would have connections to (from) corresponding circuitry, including the PLLs, in the core area 114. Paths 131 and 132 are examples of such connections, and are described below.

Input/output (bidirectional) port 145 is shown connected to package pins 122 [0 . . . n], and represents a serial communication port (e.g., according to serial interface standards I²C/SPI). A user of IC 100 is facilitated to write to/read from configurable volatile registers (contained in core 114 but not shown in FIG. 1) using the serial interface via pins 122 [0 . . . n]/port 145 via path 147 in a known way. Port 145 would be powered by VDDIO 189 (described below).

Port 130 of IC 100 is shown connected to package pin 125. IC 100 would typically have many more of such I/O ports (bidirectional and/or unidirectional), but not shown in FIG. 1 for conciseness. An example of one such I/O port is a ‘reset port’ that receives a reset signal (RSTB/active low) from an external device or power-ON reset circuit/chip.

Binary outputs to be transmitted from port 130 are received on path 132 from corresponding circuit in core 114, and buffered through tri-state buffer 136 and provided on pad 135 and to package pin 125. External binary inputs (e.g., reset signal) to be received at port 130 from an external source and via package pin 125 and pad 135 are buffered by buffer 137 and forwarded to core 114 on path 131.

An output signal from core 114 may be received at package pin 125 via pad 135 via path 132. Diodes 133 and 134 are used as protective components to prevent large voltages at pin 125 that may be above VDDIO or below ground from damaging circuitry in IC 100. ESD clamp 140 (in combination with diodes 133 and 134) is used to prevent electrostatic discharge (ESD) on pin 125 from damaging circuitry in IC 100. Capacitor 144 is a power-supply decoupling capacitor. Although not shown in the Figure, each of buffers 136 and 137 would be powered by VDDIO 189. Port 145 would have respective diodes, buffers, ESD clamp(s) and decoupling capacitor(s), not shown in FIG. 1 in the interest of conciseness.

IC 100 is shown as using two power supplies 165 (LDO1) and 175 (LDO2) for its operation. Each of LDOs 165 and 175 represents a low-dropout regulator and receives power from a power-source connected to path 101. Other types of voltage regulators can be used in place of LDO1 and LDO2. In an embodiment, LDO1 provides 3.3V on path 123 while LDO2 generates 1.8V on path 124. Pins 123 and 124 are respectively connected to power-supply pad rings 120 and 121.

In general, several instances (e.g., millions) of ICs are fabricated in accordance with FIG. 1, and it is desirable to later (post fabrication) provide flexibility for each instance of fabricated IC to be programmable, such that a portion (e.g., input/output ports, reset port and serial communication port of IC 100) of each instance uses 1.8V or 3.3V as suited in the specific application area. Thus, respective portions of some instances of IC 100 (e.g., a first batch of ICs) may be powered using 1.8V while respective portions of a second batch of ICs may be powered using 3.3V.

Although the illustrative embodiment describes selection of the desired power supply for a portion of the IC (i.e., ports), aspects of the present disclosure are equally applicable when the entire IC (including all portions thereof) is powered by a single power supply selected from multiple unequal power supplies. Further, although the illustrative embodiment describes selection between a pair of unequal power supplies (using voltage values 3.3V and 1.8V), aspects of the present disclosure are equally applicable for selecting among multiple (more than two) unequal power supplies with different voltage values, as will be apparent to a skilled practitioner. For selecting among multiple unequal power supplies, appropriate changes to memory 160 and configuration engine circuitry may be implemented, as will be apparent to skilled practitioner by reading the disclosure herein.

The desired one of the power supply voltages based on which respective circuits are to operate may be based on configuration information stored in memory 160 or externally provided by a user via serial interface (pins 122/port 145).

VDDIO (node/path 189) represents the power supply path for the multiple I/O ports including ports 130 and 145. Path 189 may be connected to one of VDD1 and VDD2 after chip reset (the operation of IC 100 following reset being termed ‘normal operation’ herein), and the specific power supply (VDD1 or VDD2) is selected or set at power-ON (following chip reset). Depending on the configuration information, the corresponding one of switches 190 and 180 is closed following (at the end of) reset to connect the ports power supply (VDDIO) path 189 to the desired power supply VDD1 or VDD2.

Memory 160 stores application specific configuration data for configuring IC 100. Configuration data includes information for configuring the desired power supply for VDDIO, information for configuring the one or more PLLs (such as feedback divider division factor, pre-scaler values, loop bandwidth, etc.), input/output clock frequencies, etc. In general, configuration information pertaining to various application parameters based on the specific application of the IC is stored in memory 160.

In an embodiment, memory 160 is implemented as a one time programmable (OTP) memory. An OTP memory is a type of non-volatile memory in which each bit is initially at a default (unprogrammed/ initial) value (e.g., logic “0”), and can be programmed/changed to another logic value (e.g., logic “1”) only once, but not the other way round thereafter. Examples of OTP memory include flash memory, eFuse, Anti-Fuse etc.

Configuration engine 150 writes to/reads from memory 160 via path 153, and performs the configuration of IC 100 including the setting of VDDIO as noted above. Specifically, depending on the configuration information specifying a specific power supply to be selected for VDDIO, configuration engine 150 generates appropriate signals to open/close switches 180 and 190, as will be described in detail in sections below. Configuration engine 150 may be implemented in a known way.

It may be appreciated that for a circuit, depending on the specific application requirements, some users may want to specify 3.3V while other users may want to specify 1.8V for powering their respective instances of circuits. Accordingly, the circuit may be configured for operation with the desired voltage value by programming bits in memory 160 with corresponding values. However, a changed requirement may necessitate operation of the circuit with another voltage. Challenges may be presented in supporting such changing requirements due to the OTP memory having the characteristic of being programmable only once.

Aspects of the present disclosure provide such flexibility. The description is continued to illustrate example logic values of bits in memory 160 for selecting desired power supply voltage, in an embodiment of the present disclosure.

### 3. Example Configuration of OTP Bits to Select the Desired Power Supply

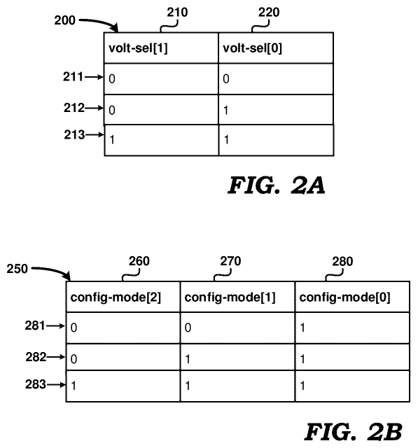

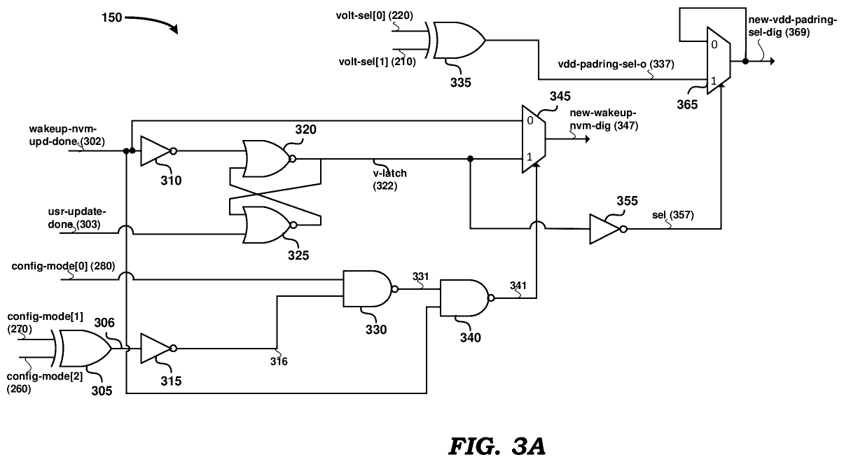

FIG. 2A depicts example logic values of power supply selection bits volt-sel[1] and volt-sel[0] in memory 160 related to configuring VDDIO power supply during normal operation of IC 100, in an embodiment of the present disclosure.

In the illustrative embodiment, the default (unprogrammed/initial) of bits in memory 160 is logic “0” and can be programmed/changed to logic “1” in-circuit only once, but not the other way round thereafter. Aspects of the present disclosure are equally applicable to OTP memories where the initial (unprogrammed) value is a logic “1”, and can be changed to logic “0” in-circuit only once, with corresponding changes to configuration engine 150, as will be apparent to a skilled practitioner.

As used herein, the term ‘manufacturer’ refers to an entity that produces (builds or fabricates) the IC, and the term ‘user’ of an IC refers to an entity that purchases the IC from the manufacturer. In the illustrative embodiment, only a manufacturer of the IC is provided ability to program power supply selection bits volt-sel[1] and volt-sel[0] in memory 160.

Table 200 lists representative configurations of bit volt-sel[1] (column 210) and bit volt-sel[0] (column 220). Rows 211-213 are shown with corresponding logic values for each of the bits, described below in detail.

In the illustrative embodiment, the result of an XOR operation of bits volt-sel[1] and volt-sel[0] determines the selection of the specific power supply to be applied to VDDIO during normal operation of IC 100. If both volt-sel[1] and volt-sel[0] have equal values (i.e., both have initial value of “0” such as in row 211, or both have programmed value of “1” such as in row 213), it corresponds to a configuration specifying that VDD2 (1.8V) is to be applied to VDDIO during normal operation of IC 100. If volt-sel[1] and volt-sel[0] have unequal values (i.e., one bit has initial value of “0” and the other bit has programmed value of “1”, such as in row 212), it corresponds to a configuration specifying that VDD1 (3.3V) is to be applied to VDDIO during normal operation of IC 100.

It is assumed that a first user wants to specify 1.8V (hereafter “first selection”) for powering their respective instances of circuits, and a second user wants to specify 3.3V (hereafter “second selection”) for powering their respective instances of circuits.

In operation, at a first time instance (e.g., at the time of manufacture of IC 100, prior to shipping to any users), in a first batch of ICs both volt-sel[1] and volt-sel[0] have the initial value of logic “0” (row 211). Thus, the first batch of ICs are purchased by the first user.

At a second time instance (e.g., prior to shipping the ICs to the second user) following the first time instance, for a second batch of ICs, the manufacturer programs bit volt-sel[0] to logic value “1” (row 212), changing the power supply configuration from the first selection to the second selection. Thus, the second batch of ICs are purchased by the second user after the second time instance.

It is assumed that after the purchase of the second batch of ICs, the second user has a changed requirement to operate their instances (batch) of circuits with 1.8V instead of 3.3V. Accordingly, at a third time instance following the second time instance, to accommodate the changed requirement, the manufacturer programs bit volt-sel[1] to logic value “1” (row 212) in the second batch of ICs. As a result of such programming, the power supply configuration reverts to the first selection (from the second selection).

It may be appreciated that if one bit (e.g., volt-sel[0]) had been used to select between a pair of unequal power supplies (with volt-sel[0]=0 indicating 1.8V and volt-sel[0]=1 indicating 3.3V), it would have been possible to only change from the first selection (1.8V) to the second selection (3.3V), but not to revert to the first selection by performing an in-circuit change. This is so due to the OTP memory having the characteristic of being programmable only once.

Usage of an additional bit (volt-sel[1]) provides the flexibility to revert to the first selection from the second selection, thus facilitating up to two changes (first selection to second selection, and then back to first selection). It may thus be appreciated that each additional OTP bit provides an extra opportunity to switch between the selections.

For example, a third bit (volt-sel[2] not shown in FIG. 2A) may be used to further revert from the first selection to the second selection at a fourth time instance following the third time instance, thus permitting up to three changes. In an embodiment, when the third bit is used additionally, the result of an XOR operation of volt-sel[2] and volt-sel[1] is in turn XOR-ed with volt-sel[0] to determine the final selection.

In general, the technique may be extended to provide the flexibility to change selections up to N times by using N OTP bits. The bits may be relatively XOR-ed to determine the final selection, as will be apparent to a skilled practitioner by reading the disclosure herein.

The description is continued to illustrate a second usage scenario where the above noted technique is applied to provide flexibility in a mode of configuring the desired power supply for VDDIO.

### 4. Example Configuration of OTP Bits to Select a Mode of Configuring the Desired Power Supply

FIG. 2B depicts example logic values of bits config-mode[2], config-mode[1] and config-mode[0] in memory 160 related to a mode of configuring the desired power supply for VDDIO. Specifically, in a first mode, the user is provided an option to specify (select) the power supply for VDDIO via serial interface (pins 122/port 145), as will be described in detail below. In a second mode, the power supply for VDDIO is configured by the manufacturer of IC 100 by specifying the corresponding values in OTP bits volt-sel[1] and volt-sel[0].

Table 250 lists representative configurations of bit config-mode[2] (column 260), bit config-mode[1] (column 270) and bit config-mode[0] (column 280). Rows 281-283 are shown with corresponding logic values for each of the bits, described below in detail.

In the illustrative embodiment, the result of an XOR operation of bits config-mode[1] and config-mode[2] determines the selection of mode of configuring the desired power supply for VDDIO.

If both config-mode[1] and config-mode[2] have equal values (i.e., both have initial value of “0” such as in row 281, or both have programmed value of “1” such as in row 283), it corresponds to the first mode noted above. If config-mode[1] and config-mode[0] have unequal values (i.e., one bit has initial value of “0” and the other bit has programmed value of “1”, such as in row 282), it corresponds to the second mode noted above. The combination of having logic value of “0” in both config-mode[0] and config-mode[1] (not shown in FIG. 2B) is used for some other purpose not within the scope of this disclosure.

It is assumed that a third user wants to select the desired power supply for VDDIO (“first mode” noted above) for their respective instances of circuits, and a fourth user wants the manufacturer to configure the desired power supply for VDDIO (“second mode” noted above) for their respective instances of circuits.

In operation, at a first time instance, (e.g., prior to shipping to the third user), for a third batch of ICs, the manufacturer programs config-mode[0] to logic value “1” and retains initial value of logic “0” in bits config-mode[2] and config-mode[1] (row 281). Thus, the third batch of ICs are purchased by the third user. User input received via the serial interface determines the power supply for VDDIO for these ICs. It is noted herein that the register addresses of the configurable volatile registers and the specific values to be updated in the registers (based on the desired selection) may be conveyed to user in a known way, such as via an application note delivered along with ICs, as will be apparent to a skilled practitioner.

At a second time instance (e.g., prior to shipping to the fourth user), for a fourth batch of ICs, the manufacturer programs bits config-mode[1] to logic value “1” (row 282), changing the mode from the first mode to the second mode. Thus, the fourth batch of ICs are purchased by the fourth user. Values in bits volt-sel[1] and volt-sel[0] specified by the manufacturer determine the power supply for VDDIO for these ICs.

Users are facilitated to update/write to designated volatile registers during power-ON of IC 100 in order to select the desired power supply for VDDIO. As is well known in the relevant arts, using a reset signal (RSTB/active low applied at port 130, for example), IC 100 is initialized to a known base state from which it can start operating, with all the configurable registers, connections, etc., in the circuitry in IC 100 including those in core 114 (such as PLLs) being initialized to known initial values/states.

In an embodiment, when signal RSTB equals logic low, chip is in reset. RSTB is asserted to logic high (to release chip from reset) after a pre-determined duration, and IC 100 begin its normal operation. The time/duration (reset duration) for which the reset signal is to remain logic low may be dependent on the specific implementation of the circuits/blocks in IC 100. As used herein, the term ‘normal operation’ is used to refer to operations of IC 100 upon exit from reset operation. The sequence of operations during power-ON (PSEQ) is driven by a reset state machine logic (not shown), as is well known in the relevant arts.

Typically, two types of ‘resets’ are available to reset IC 100—a hard reset and a soft reset. A ‘hard reset’ is initiated by applying appropriate external input on a RSTB pin, or a power cycle (disconnecting IC 100 from the power source and re-connecting). A hard reset restores all volatile registers, including the ones to which contents from memory 160 are copied, in IC 100 to the corresponding default values (e.g., logic “0”). A ‘soft reset’ is initiated by asserting a designated bit in IC 100 to cause reset of IC 100. A soft reset restores all volatile registers, excluding the ones to which contents from memory 160 are copied, in IC 100 to the corresponding default values.

Configuration engine 150 connects VDDIO to the desired power supply based on the above noted configuration of bits in memory 160 or user input. Accordingly, the description is continued to illustrate an example implementation of configuration engine 150 according to aspects of the present disclosure.

### 5. Configuration Engine

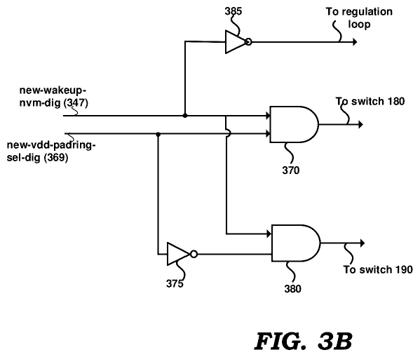

FIGS. 3A and 3B are diagrams illustrating an example implementation of a configuration engine in an embodiment of the present disclosure. Configuration engine 150 is shown containing XOR gates 305 and 335, inverters 310, 315, and 355, NOR gates 320 and 325 forming an SR latch, NAND gates 330 and 340, and multiplexers (MUXes) 345 and 365. FIG. 3B is shown containing AND gates 370 and 380, and inverters 375 and 385.

Configuration engine 150 reads logic values of bits config-mode[0] (280), config-mode[1] (270), config-mode[2] (260), volt-sel[0] (220), and volt-sel[1] (210). In an embodiment, configuration engine 150 copies (downloads) the logic values to respective volatile registers upon release of reset. Signals on path 302 and 303 respectively correspond to outputs of registers ‘wakeup-nvm-upd-done’ and ‘usr-update-done’. It is noted herein that the outputs of registers and the registers are referred to by the same label/name for simplicity.

Configuration engine 150 generates signals ‘new-vdd-padring-sel-dig’ on path 369 and ‘new-wake-up-nvm-dig’ on path 347. Value on path 337 represents result of XOR operation of OTP bits volt-sel[0] and volt-sel[1] which is used to determine the desired power supply for VDDIO. User is facilitated to specify the specific power supply for VDDIO by writing to registers volt-sel[0] and volt-sel[1] via pins 122/serial port 145 using any convenient means, such as a computer/microcontroller/electronic device.

Logic value in volatile register ‘wakeup-nvm-upd-done’ indicates whether copying of contents from memory 160 to corresponding volatile registers is complete or not. In an embodiment, when signal RSTB equals logic low (chip is in reset), ‘wakeup-nvm-upd-done’ is a logic low. After RSTB is asserted to logic high (to release chip from reset), contents of memory 160 are downloaded to corresponding volatile registers. Signal ‘wakeup-nvm-upd-done’ is asserted (to logic high) upon completion of the download by reset state machine logic. Signal ‘wakeup-nvm-upd-done’ remains asserted till a subsequent hard reset of IC 100 is initiated (by using RSTB pin or a power cycle). A soft reset of IC 100 retains the logic value in register ‘wakeup-nvm-upd-done’.

Register ‘usr-update-done’ is written to by user via pins 122 after writing to registers volt-sel[0] and volt-sel[1]. In an embodiment, a logic high in ‘usr-update-done’ indicates that the user has completed specifying the power supply selection, and a logic low indicates otherwise. In the second mode, ‘usr-update-done’ remains at logic low.

Signal ‘new-wake-up-nvm-dig’ indicates whether configuration of power supply of VDDIO is complete or not. In an embodiment, a logic high on ‘new-wake-up-nvm-dig’ indicates that the configuration is complete, and a logic low indicates otherwise. Reset state machine logic executes any remaining wake-up operations only after ‘new-wake-up-nvm-dig’ is asserted.

Logic value of ‘new-vdd-padring-sel-dig’ determines the opening and closing of switches 180 and 190 in order to connect VDDIO to one of VDD1 and VDD2 during normal operation of IC 100 after chip reset. In an embodiment, when ‘new-vdd-padring-sel-dig’ is a logic high, power supply node of VDDIO during normal operation is connected to VDD1, and is connected to VDD2 otherwise.

The manner in which a configuration engine operates to select the desired power supply according to aspects of the present disclosure is described below with examples.

### 6. Setting a Specific Power Supply for VDDIO

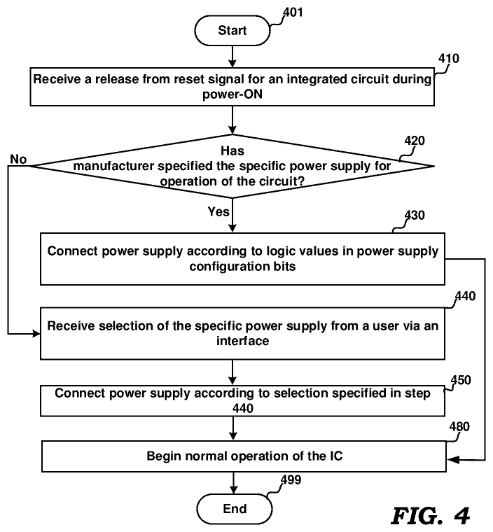

FIG. 4 is a flow-chart illustrating the manner in which a configuration engine operates to select desired power supply for ICs based on OTP memory, in an embodiment of the present disclosure. While the description is provided with specific examples with reference to components of FIGS. 1, 3A and 3B, the features of the present disclosure can be employed in the corresponding circuitry/sub-systems in other component and environment without departing from the scope and spirit of various aspects of the present disclosure, as will be apparent to one skilled in the relevant arts by reading the disclosure provided herein.

In addition, some of the steps may be performed in a different sequence than that depicted below, as suited to the specific environment, as will be apparent to one skilled in the relevant arts. Many of such implementations are contemplated to be covered by several aspects of the present disclosure. The flow chart begins in step 401, in which control immediately passes to step 410.

In step 410, a release from reset signal is received for IC 100 from an external source during power-ON. It is assumed that a reset signal received from the external source has initiated the reset of IC 100 prior to step 410. Control passes to step 420.

In step 420, configuration engine 150 checks whether a manufacturer has specified the specific power supply for operation of the circuit. Configuration engine 150 examines the logic values in bits config-mode[2], config-mode[1] for such determination. If it is determined that the manufacturer has specified the specific power supply, control passes to step 430 (YES), and to step 440 (NO) otherwise.

In step 430, configuration engine 150 connects the desired power supply for operation of the circuit according to logic values in power supply configuration bits volt-sel[0], volt-sel[1]. As noted above, the manufacturer specifies the specific power supply by setting bits volt-sel[0], volt-sel[1] prior to shipping the IC to a user. Control passes to step 480.

In step 440, configuration engine 150 receives selection of the specific power supply from a user via an interface (such as the serial interface noted above in FIG. 1). Control passes to step 450.

In step 450, configuration engine connects the desired power supply for operation of the circuit according to selection specified by the user in step 440. Control passes to step 480.

In step 480, IC 100 begins its normal operation. As noted above, the operation of IC 100 following reset is termed as ‘normal operation’ herein. The flow-chart ends in step 499.

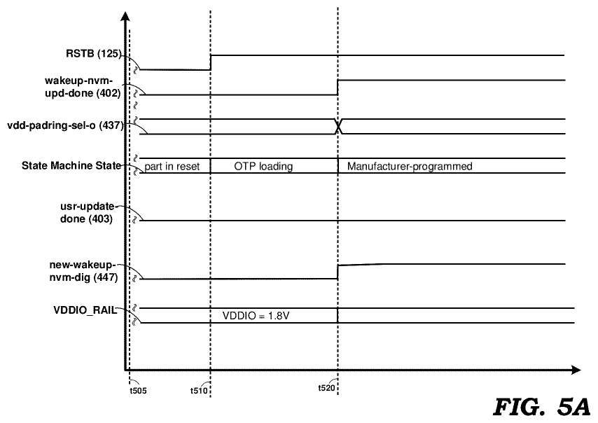

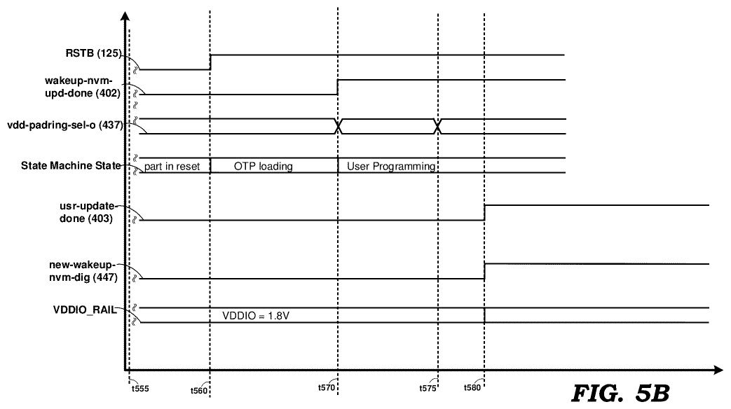

The description is continued to illustrate the operation of configuration engine with reference to timing diagrams of FIGS. 5A and 5B in an embodiment of the present disclosure.

FIGS. 5A and 5B are timing diagrams (not to scale) illustrating logic values of various signals/registers, VDDIO_RAIL (power supply rail of VDDIO 189) during reset and until the start of normal operation of IC 100, in an embodiment of the present disclosure.

FIG. 5A illustrates example values for the scenario in which a manufacturer of IC 100 has specified a specific power supply for VDDIO. FIG. 5B illustrates example values for the scenario in which a user of IC 100 specifies the specific power supply. Each of timing diagrams 5A and 5B illustrates logic values of signals RSTB (active low reset) (125), wakeup-nvm-upd-done (402), vdd-padring-sel-o (437), usr-update-done (403), new-wake-up-nvm-dig (447) and state of VDDIO_RAIL. The Figures also depict current state of the reset state machine in the duration noted above.

In the illustrative embodiment, a regulation loop (not shown) operates to provide on path VDDIO a power supply voltage equal to VDD2 (1.8V) that is derived from VDD1 (3.3V). An example implementation of regulation loop 250 is described in the U.S. Pat. No. 12,026,028, which is incorporated its entirety herewith. Configuration engine 150 performs the configuration of IC 100 (including setting of VDDIO), and upon completing the configuration causes regulation loop 250 to become non-operational via corresponding means (e.g., by opening a switch connecting VDDIO to the regulation loop).

### A. Manufacturer Has Specified the Specific Power Supply

It is assumed that bits config-mode[0]-config-mode[2] have logic values as depicted in row 282 of table 250 (FIG. 2B).

Prior to t505, it is assumed that RSTB pin (125) is pulled low to reset chip 100. RSTB is held low for the reset duration ending at t510 and accordingly chip is in reset (state=‘part in reset’) until time t510.

In the duration t505-t510, VDDIO_RAIL is set to 1.8V by the regulation loop for the reset release to reliably occur. Values ‘wakeup-nvm-upd-done’ and ‘usr-update-done’ equal logic low. Accordingly, value of v-latch (322) equals logic low. Logic values volt-sel[0], volt-sel[1], config-mode[0], config-mode[1] and config-mode[2] are logic low (default value) since contents from memory 160 have not been copied to the corresponding registers. Thus, both inputs to XOR gate 305 are logic low. Accordingly, output on path 306 equals logic low, and value on path 316 equals logic high. Accordingly, value on path 331 equals logic high, and value on path 341 equals logic high, and MUX 345 forwards value of v-latch (logic low) on path ‘new-wake-up-nvm-dig’. Value of bit sel (357) is logic high, and MUX 365 forwards the value of vdd-padring-sel-o (337) on path ‘new-vdd-padring-sel-dig’ (369).

Inputs to XOR gate 335 are both logic low, and thus signal ‘vdd-padring-sel-o’ is logic low. Accordingly, ‘new-vdd-padring-sel-dig’ is a logic low. Referring to FIG. 4B, outputs of both AND gates 370 and 380 are logic low. Thus, switches 180 and 190 are open. Output of inverter 385 is logic high, thus keeping regulation loop operational.

At t510, RSTB is pulled to logic high to release the chip from reset (step 410). Configuration engine 150 reads values of bits volt-sel[0], volt-sel[1], and config-mode[0]-config-mode[2] from memory 160. Signal ‘vdd-padring-sel-o’ is updated with XOR output of volt-sel[0] and volt-sel[1]. State is shown as ‘OTP loading’. VDDIO_RAIL continues to be at 1.8V. Configuration engine 150 determines that the manufacturer has specified the specific power supply (branch YES in step 420).

Inputs to XOR gate 305 are logic high (config-mode[1]) and logic low (config-mode[2]). Accordingly, output on path 306 equals logic high, and value on path 316 equals logic low. Accordingly, value on path 331 equals logic high. Values ‘wakeup-nvm-upd-done’ and ‘usr-update-done’ continue to be logic low. Accordingly, value on path 341 equals logic high, and MUX 345 forwards value of v-latch (logic low) on path ‘new-wake-up-nvm-dig’.

At t520, upon completion of reading of contents of memory 160, reset state machine logic asserts ‘wakeup-nvm-upd-done’ to logic high. Inputs to NAND gate 340 are now both logic high. Accordingly, value on path 341 equals logic low. Therefore, MUX 345 forwards the value of ‘wakeup-nvm-upd-done’ (logic high) on path ‘new-wake-up-nvm-dig’ (shown to change to logic high at t520), and MUX 365 continues to forward the value of vdd-padring-sel-o (337) on path ‘new-vdd-padring-sel-dig’ (369).

Since manufacturer has specified the specific power supply, user does not assert value of ‘usr-update-done’. Therefore, value of ‘usr-update-done’ continues to be logic low.

Thus, at t520, the specific power supply configured in volt-sel[0], volt-sel[1] is used to select VDDIO power supply (step 430). At t520 or slightly later (upon completion of all power-ON initialization operations), IC 100 begins its normal operation (step 480). For example, if the manufacturer has specified volt-sel[0]=0, volt-sel[1]=0 (indicating LDO2), ‘new-vdd-padring-sel-dig’ equals logic low. Accordingly, referring to FIG. 3B, inverter 375 is a logic high, thereby resulting in closing of switch 180 (FIG. 1), thus connecting VDDIO to LDO2. Output of AND gate 370 is a logic low, thereby keeping switch 190 open. Output of inverter 385 is a logic low, thereby making regulation loop non-operational.

### B. User Selects the Specific Power Supply

It is assumed that bits config-mode[0]-config-mode[2] have logic values as depicted in row 281 of table 250 (FIG. 2B).

Referring to FIG. 5B, prior to t555, it is assumed that RSTB pin (125) is pulled low to reset chip 100. RSTB is held low for the reset duration ending at t560 and accordingly chip is in reset (state=‘part in reset’) until time t560.

In the duration t555-t560, signals have values similar to those depicted in the duration t505-t510 with respect to FIG. 5A, and the description is not repeated here in the interest of conciseness.

At t560, RSTB is pulled to logic high to release the chip from reset (step 410). Configuration engine 150 reads values of bits volt-sel[0], volt-sel[1], and config-mode[0], config-mode[1], and config-mode[2] from memory 160. Register ‘vdd-padring-sel-o’ is updated with XOR output of volt-sel[0] and volt-sel[1]. State is shown as ‘OTP loading’. VDDIO_RAIL continues to be at 1.8V. Configuration engine 150 determines that the manufacturer has not specified the specific power supply (branch NO in step 420). In an embodiment, when user has to specify the specific power supply, bits volt-sel[0] and volt-sel[1] are left unprogrammed by the manufacturer and have initial value (logic low), corresponding to VDD2 (1.8V). Thus, ‘vdd-padring-sel-o’ is a logic low.

Inputs to XOR gate 305 are both logic low. Accordingly, output on path 306 is a logic low, and value on path 316 equals logic high. Accordingly, value on path 331 equals logic low. Values ‘wakeup-nvm-upd-done’ and ‘usr-update-done’ continue to be logic low. Accordingly, value on path 341 equals logic high, and MUX 345 forwards value of v-latch (logic low) on path ‘new-wake-up-nvm-dig’. Value of select signal sel (357) is logic high, and MUX 365 forwards the value of vdd-padring-sel-o (337) on path ‘new-vdd-padring-sel-dig’ (469).

At t570, upon completion of reading of contents of memory 160, reset state machine logic asserts ‘wakeup-nvm-upd-done’ to logic high. Value of v-latch continues to be logic low. Inputs to NAND gate 340 are now logic high (‘wakeup-nvm-upd-done’) and logic low (output of NAND gate 430). Accordingly, value on path 341 equals logic high, and accordingly, MUX 345 forwards value of v-latch (logic low) on path ‘new-wake-up-nvm-dig’. Thus, referring to FIG. 3B, outputs of AND gates 370 and 380 are logic low, thereby continuing to keep switches 180 and 190 open. Output of inverter 385 is logic high, thus keeping regulation loop operational.

Though memory contents have been read, ‘new-wake-up-nvm-dig’ continues to be logic low, implying that regulation loop continues to be used as power supply for VDDIO. Thus, VDDIO_RAIL is shown to continue at 1.8V. IC 100 will stay in this condition until user writes to volatile registers volt-sel[0] and volt-sel[1] (via pins 122) to configure the specific power supply, and thereafter updates ‘usr-update-done’ to logic high.

In an embodiment, the user is enabled to write to volatile registers volt-sel[0] and volt-sel[1] after a pre-determined blank-out duration has elapsed after RSTB pin is pulled to logic high. The blank-out duration is depicted as duration t560-t570 in FIG. 5B. In the embodiment, the blank-out duration is 0.5 milli seconds. In general, the blank-out duration is configured to provide sufficient time for memory contents to be read (and downloaded to corresponding volatile registers), as will be apparent to a skilled practitioner by reading the disclosure herein.

In the duration t570-t575, user writes to volatile registers volt-sel[0]/volt-sel[1] via pins 122/serial port 145 (step 440). For example, in order to specify that VDD1 (3.3V) is to be applied to VDDIO, user writes logic “1” to volt-sel[0] and retains logic “0” in volt-sel[1]. Accordingly, ‘vdd-padring-sel-dig’ is a logic high.

At t580, user sets ‘usr-update-done’ value to logic high. When value in ‘usr-update-done’ is logic high, value of v-latch changes from logic low to logic high. Accordingly, signal ‘new-wake-up-nvm-dig’ changes to logic high, thereby output of inverter 385 is a logic low, making regulation loop non-operational. Also, select bit (357) of MUX 365 changes to logic low, and value of ‘vdd-padring-sel-o’ (logic high in the example) is latched at output ‘new-vdd-padring-sel-dig’ of MUX 365. Referring to FIG. 3B, output of AND gate 370 is a logic high and output of AND gate 380 is a logic low. Thus, switch 190 is closed (connecting VDDIO to VDD1) and switch 180 continues to be open.

Thus, at t580, the specific power supply configured in registers volt-sel[0], volt-sel[1] is used to select VDDIO power supply (step 450). At t580 or slightly later (upon completion of all power-ON initialization operations), IC 100 begins its normal operation (step 480).

It may be appreciated that the user may not want to update the desired power supply selection whenever a soft reset of IC 100 is performed. Registers volt-sel[0], volt-sel[1], ‘usr-update-done’, and ‘wakeup-nvm-upd-done’ are excluded from soft reset, thereby retaining the desired power supply selection specified by user. In other words, assuming that a soft reset occurs at some time after t580, register ‘wakeup-nvm-upd-done’ will continue to be logic high, and registers volt-sel[0] and volt-sel[1] will continue to retain the values programmed by user at t575. Whenever a hard reset is performed, user has to write to registers volt-sel[0] and volt-sel[1], and thereafter assert ‘usr-update-done’ in order to specify the desired power supply for VDDIO. In an alternative embodiment, values written to by user in registers volt-sel[0] and votl-sel[1] are burnt to memory 160 by configuration engine 150.

The description is continued to illustrate the usage of bit config-mode[2] to provide the flexibility to change a mode of configuration of power supply for VDDIO, in an embodiment of the present disclosure.

### 7. Providing Flexibility to Change a Mode of Configuration of Power Supply

As noted above, a requirement of a user with respect to power supply setting may change after the ICs are received from the manufacturer. For example, assume that a user has an initial requirement that a batch of ICs be programmed by the manufacturer (second mode noted above) to be used with 3.3V power supply prior to shipping. Thus, bits config-mode[0]-config-mode[2] are programmed as per values in row 282 (of FIG. 2B), and bits volt-sel[0] and volt-sel[1] are programmed as per values in row 212.

Due to a changed requirement, user now needs VDDIO ports (of the batch of ICs) that were configured to be used with 3.3V to be configured with 1.8V. However, since the user has received ICs that are deigned to operate in the second mode (manufacturer-programmed power supply selection), the user is not provided the option to select the desired power supply during power-ON of IC 100. Also, since bits config-mode[1] and config-mode[0] have already been programmed to logic value “1”, it is not possible to revert to logic “0”in-circuit.

In such a scenario, according to aspects of the present disclosure, the user is facilitated to write to/change config-mode[2] to logic “1” (from the default unprogrammed value of logic “0”) via serial interface. In an embodiment, the user writes to config-mode[2] for each instance of IC in the batch of ICs after the pre-determined blank-out duration noted above, and configuration engine 150 burns bit config-mode[2] in respective memory 160 in each instance in a known way. Thus, after such reconfiguration, logic values in bits config-mode[0]-config-mode[2] have values as depicted in row 283 of FIG. 2B.

During a next (subsequent) power-ON reset of IC 100 after the above noted reconfiguration of config-mode[2], the user is provided the option to select the desired power supply by to writing to/changing volt-sel[1] to logic “1” (from the default unprogrammed value of logic “0”) via serial interface. Configuration engine 150 does not update ‘new-wake-up-nvm-dig’ value to logic high until user has asserted ‘usr-update-done’ (after writing to volt-sel[0], volt-sel[1] as noted above with respect to FIG. 5B).

It may be appreciated that if a row with values [0, 0, 0] for config-mode[0]-config-mode[2] were to be used, the user would have been facilitated one more change in mode selection.

In this manner, aspects of the present disclosure provide flexibility in selecting desired power supply for ICs based on OTP memory.

IC 100 implemented as described above can be incorporated in a larger device or system as described briefly next with an example.

### 8. System

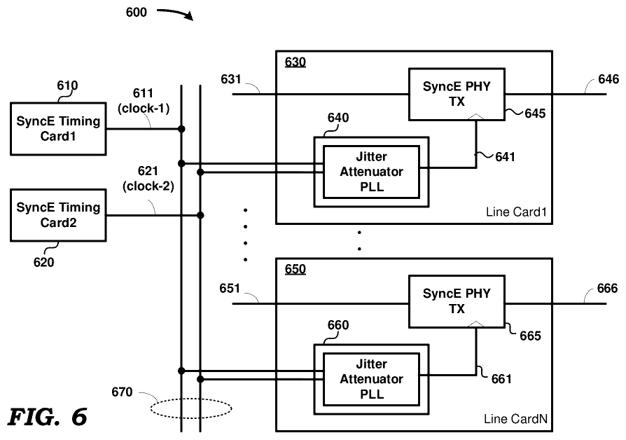

FIG. 6 is a block diagram illustrating the implementation details of a system incorporating IC 100 as described in detail above. System 600 is shown containing SyncE (Synchronous Ethernet) timing cards (610 and 620) and line cards 1 through N, of which only two line cards 630 and 650 are shown for simplicity. Line card 630 is shown containing jitter attenuator PLL 640 and SyncE PHY Transmitter 645. Line card 650 is shown containing jitter attenuator PLL 660 and SyncE PHY Transmitter 665. The components of FIG. 6 may operate consistent with the Synchronous Ethernet (SyncE) network standard. As is well known in the relevant arts, SyncE is a physical layer (PHY)-based technology for achieving synchronization in packet-based Ethernet networks. The SyncE clock signal transmitted over the physical layer should be traceable to an external master clock (for example, from a timing card such as card 610 or 620). Accordingly, Ethernet packets are re-timed with respect to the master clock, and then transmitted in the physical layer. Thus, data packets (e.g., on path 631 and 651) are re-timed and transmitted without any time stamp information being recorded in the data packet. The packets may be generated by corresponding applications such as IPTV (Internet Protocol Television), VoIP (Voice over Internet Protocol), etc.

Thus, line card 630 receives a packet on path 631, and forwards the packet on output 646 after the packet has been re-timed (synchronized) with a master clock. Similarly, line card 650 receives a packet on path 651, and forwards the packet on output 666 after the packet has been re-timed (synchronized) with a master clock.

The master clock (611/clock 1) is generated by timing card 610. Timing card 620 generates a redundant clock (621/clock-2) that is to be used by line cards 630 and 650 upon failure of master clock 611. Master clock 611 and redundant clock 621 are provided via a backplane (represented by numeral 670) to each of lines cards 630 and 650.

In line card 630, jitter attenuator PLL 640 may be implemented as IC 100 described above in detail, and receives clocks 611 and 621. Alternatively, line card 630 may be implemented to contain jitter attenuator PLL 640 as a separate block, with the I/O ports described above. PLL 640 generates an output clock 641 which is used to synchronize (re-time) packets received on path 631 and forwarded as re-timed packets on path 646.

Similarly, in line card 650, jitter attenuator PLL 660 may also be implemented as IC 600 described above in detail, and receives clocks 611 and 621. Alternatively, line card 650 may be implemented to contain jitter attenuator PLL 660 as a separate block, with the I/O ports described above. PLL 660 generates an output clock 661 which is used to synchronize (re-time) packets received on path 651 and forwarded as re-timed packets on path 666.

Similar to IC 100 described above, each of line cards 630 and 650 too has a reset operation (when being reset to initialize all the circuits, including PLL, I/O ports, etc., on the corresponding line card) and a normal operation post the reset operation. In an embodiment, each line cards 630 and 650 is based on OTP memory, and flexibility is provided in selecting the desired power supply for the line cards, as described above.

Implementation of the jitter attenuator PLLs 640 and 660 as IC 100, or alternatively implementation of line cards 630 and 650 with PLL, I/O circuitry and power supply configuration circuitry as separate blocks and in discrete form provides the flexibility to select desired power supply for IC 100 (or portions thereof).

### 9. Conclusion

References throughout this specification to “one embodiment”, “an embodiment”, or similar language means that a particular feature, structure, or characteristic described in connection with the embodiment is included in at least one embodiment of the present disclosure. Thus, appearances of the phrases “in one embodiment”, “in an embodiment” and similar language throughout this specification may, but do not necessarily, all refer to the same embodiment.

While in the illustrations of FIGS. 1, 3A, 3B and 6 although terminals/nodes are shown with direct connections to (i.e., “connected to”) various other terminals, it should be appreciated that additional components (as suited for the specific environment) may also be present in the path, and accordingly the connections may be viewed as being “electrically coupled”to the same connected terminals.

It should be appreciated that the specific type of transistors (such as NMOS, PMOS, etc.) noted above are merely by way of illustration. However, alternative embodiments using different configurations and transistors will be apparent to one skilled in the relevant arts by reading the disclosure provided herein. For example, the NMOS transistors may be replaced with PMOS (P-type MOS) transistors, while also interchanging the connections to power and ground terminals.

Accordingly, in the instant application, the power and ground terminals are referred to as constant reference potentials, the source (emitter) and drain (collector) terminals of transistors (though which a current path is provided when turned on and an open path is provided when turned off) are termed as current terminals, and the gate (base) terminal is termed as a control terminal.

While various embodiments of the present disclosure have been described above, it should be understood that they have been presented by way of example only, and not limitation. Thus, the breadth and scope of the present disclosure should not be limited by any of the above-described embodiments, but should be defined only in accordance with the following claims and their equivalents.

What is claimed is:

1. An integrated circuit (IC) comprising:
a circuit to be operable using one of a plurality of unequal power supplies during normal operation of said IC;
a one time programmable (OTP) memory containing a first bit and a second bit, each of said first bit and said second bit having an initial value and being programmable to a programmed value; and
a configuration engine to operate said circuit with a first selection with respect to using one of said plurality of unequal power supplies during normal operation of said IC if both of said first bit and said second bit have an equal value comprising one of said initial value and said programmed value,
said configuration engine to operate said circuit with a second selection with respect to using one of said plurality of unequal power supplies during normal operation of said IC if said first bit and said second bit have unequal values.

2. The integrated circuit of claim 1, wherein said configuration engine comprises an XOR gate for performing an XOR operation of said first bit and said second bit to determine said first selection or said second selection.

3. The integrated circuit of claim 1, wherein both of said first bit and said second bit have said initial value at a first time instance,
wherein only said first bit is programmed to said programmed value at a second time instance following said first time instance to change from said first selection to said second selection,
wherein said second bit is then programmed to said programmed value at a third time instance following said second time instance to revert back to said first selection.

4. The integrated circuit of claim 3, wherein said first selection comprises a first power supply and said second selection comprises a second power supply, said first power supply and said second power supply being comprised in said plurality of unequal power supplies,
wherein said circuit is operated using said first power supply when both of said first bit and said second bit have equal value,
wherein said circuit is operated using said second power supply when both of said first bit and said second bit have unequal values.

5. The integrated circuit of claim 4, wherein only a manufacturer of said integrated circuit is provided ability to program said first bit and said second bit,
wherein said manufacturer programs said first bit to said programmed value to indicate said second selection at said second time instance and then programs said second bit at said third time instance to said programmed value to indicate said first selection.

6. The integrated circuit of claim 5, wherein said OTP memory further comprises a third bit and a fourth bit,
wherein a manufacturer specifies said selection when both said third bit and said fourth bit have unequal values,
wherein a user is provided an option to specify whether to use said first power supply or said second power supply when said third bit and said fourth bit have equal value,
wherein said manufacturer specifies said selection in said first bit and said second bit.

7. The integrated circuit of claim 6, wherein said OTP memory comprises a fifth bit, wherein said configuration engine comprises:
a first inverter coupled to receive a first wake-up signal, and to generate a first-inverter-output, wherein a logic value of said first wake-up signal indicates whether values of said first bit, said second bit, said third bit and said fourth bit have been downloaded from said OTP memory to respective volatile registers, wherein a logic high of said first wake-up signal indicates that said download is complete, and a logic low of said first wake-up signal indicates otherwise;
a first XOR gate coupled to receive said third bit and said fourth bit, and to generate a first-XOR-output;
a second inverter coupled to receive said first-XOR-output and to generate a second-inverter-output;
an SR-latch coupled to receive a user-update-done signal at the set-input and said first-inverter-output at the reset-input, said SR-latch to generate a latched-value at the Q-output;
a third inverter coupled to receive said latched-value and to generate a third-inverter-output;
a first NAND gate coupled to receive said fifth bit and said second-inverter-output, and to generate a first-NAND-output;
a second NAND gate coupled to receive said first-NAND-output and said first wake-up signal, and to generate a second-NAND-output;
a first multiplexer (MUX) coupled to receive said first wake-up signal and said latched-value as inputs, said second-NAND-output as a select signal, said first MUX to forward said latched-value as a second wake-up signal if said second-NAND-output is a logic high, said first MUX to forward said first wake-up signal as said second wake-up signal if said second-NAND-output is a logic low;
a second XOR gate coupled to receive said first bit and said second bit, and to generate a second XOR-output;
a second MUX coupled to generate a selected-power-supply-value, said MUX coupled to receive said second XOR-output and said selected-power-supply-value as inputs, said third-inverter-output as a select signal, said second MUX to forward said second XOR-output as said selected-power-supply-value if said third-inverter-output is a logic high, said second MUX to latch said selected-power-supply-value at the output of said second MUX if said third-inverter-output is a logic low;
a fourth inverter coupled to receive said second wake-up signal, and to generate a first control signal;
a fifth inverter coupled to receive said selected-power-supply-value, and to generate a fifth-inverter-output;
a first AND gate coupled to receive said second wake-up signal and said selected-power-supply-value, and to generate a second control signal; and
a second AND gate coupled to receive said second wake-up signal and said fifth-inverter-output, and to generate a third control signal.

8. The integrated circuit of claim 7, further comprising:
a first switch coupled between a power supply node of said circuit and said first power supply, wherein said first switch is operable to be closed or open based on a logic value of said second control signal; and
a second switch coupled between said power supply node of said circuit and said second power supply, wherein said second switch is operable to be closed or open based on a logic value of said third control signal.

9. The integrated circuit of claim 3, wherein said first selection and said second selection comprise whether a manufacturer of said IC or a user of said IC specifies a desired one of said plurality of unequal power supplies to operate said circuit.

10. The integrated circuit of claim 3, wherein said OTP memory comprises a third bit, which upon being programmed to said programmed value at a fourth time instance following said third time instance further reverts back from said first selection to said second selection.

11. A system comprising:
a first timing card to generate a first clock; and
a line card coupled to receive a data packet, said line card to re-time said data packet, and to transmit a re-timed packet, wherein said line card comprises:
a phase-locked loop (PLL) coupled to receive said first clock, said PLL to generate an output clock based on said first clock, wherein said line card retimes said data packet with respect to said output clock;
a circuit to be operable using one of a plurality of unequal power supplies during normal operation of said line card;
a one time programmable (OTP) memory containing a first bit and a second bit, each of said first bit and said second bit having an initial value and being programmable to a programmed value; and
a configuration engine to operate said circuit with a first selection with respect to using one of said plurality of unequal power supplies during normal operation of said line card if both of said first bit and said second bit have an equal value comprising one of said initial value and said programmed value,
said configuration engine to operate said circuit with a second selection with respect to using one of said plurality of unequal power supplies during normal operation of said line card if said first bit and said second bit have unequal values.

12. The system of claim 11, wherein said configuration engine comprises an XOR gate for performing an XOR operation of said first bit and said second bit to determine said first selection or said second selection.

13. The system of claim 11, wherein both of said first bit and said second bit have said initial value at a first time instance,
wherein only said first bit is programmed to said programmed value at a second time instance following said first time instance to change from said first selection to said second selection,
wherein said second bit is then programmed to said programmed value at a third time instance following said second time instance to revert back to said first selection.

14. The system of claim 13, wherein said first selection comprises a first power supply and said second selection comprises a second power supply, said first power supply and said second power supply being comprised in said plurality of unequal power supplies,
wherein said circuit is operated using said first power supply when both of said first bit and said second bit have equal value,
wherein said circuit is operated using said second power supply when both of said first bit and said second bit have unequal values.

15. The system of claim 14, wherein only a manufacturer of said integrated circuit is provided ability to program said first bit and said second bit, wherein said manufacturer programs said first bit to said programmed value to indicate said second selection at said second time instance and then programs said second bit at said third time instance to said programmed value to indicate said first selection.

16. The system of claim 15, wherein said OTP memory further comprises a third bit and a fourth bit,
wherein a manufacturer specifies said selection when both said third bit and said fourth bit have unequal values,
wherein a user is provided an option to specify whether to use said first power supply or said second power supply when said third bit and said fourth bit have equal value,
wherein said manufacturer specifies said selection in said first bit and said second bit.

17. The system of claim 16, wherein said OTP memory comprises a fifth bit, wherein said configuration engine comprises:
a first inverter coupled to receive a first wake-up signal, and to generate a first-inverter-output, wherein a logic value of said first wake-up signal indicates whether values of said first bit, said second bit, said third bit and said fourth bit have been downloaded from said OTP memory to respective volatile registers, wherein a logic high of said first wake-up signal indicates that said download is complete, and a logic low of said first wake-up signal indicates otherwise;
a first XOR gate coupled to receive said third bit and said fourth bit, and to generate a first-XOR-output;
a second inverter coupled to receive said first-XOR-output and to generate a second-inverter-output;
an SR-latch coupled to receive a user-update-done signal at the set-input and said first-inverter-output at the reset-input, said SR-latch to generate a latched-value at the Q-output;
a third inverter coupled to receive said latched-value and to generate a third-inverter-output;
a first NAND gate coupled to receive said fifth bit and said second-inverter-output, and to generate a first-NAND-output;
a second NAND gate coupled to receive said first-NAND-output and said first wake-up signal, and to generate a second-NAND-output;
a first multiplexer (MUX) coupled to receive said first wake-up signal and said latched-value as inputs, said second-NAND-output as a select signal, said first MUX to forward said latched-value as a second wake-up signal if said second-NAND-output is a logic high, said first MUX to forward said first wake-up signal as said second wake-up signal if said second-NAND-output is a logic low;
a second XOR gate coupled to receive said first bit and said second bit, and to generate a second XOR-output;
a second MUX coupled to generate a selected-power-supply-value, said MUX coupled to receive said second XOR-output and said selected-power-supply-value as inputs, said third-inverter-output as a select signal, said second MUX to forward said second XOR-output as said selected-power-supply-value if said third-inverter-output is a logic high, said second MUX to latch said selected-power-supply-value at the output of said second MUX if said third-inverter-output is a logic low;
a fourth inverter coupled to receive said second wake-up signal, and to generate a first control signal;
a fifth inverter coupled to receive said selected-power-supply-value, and to generate a fifth-inverter-output;
a first AND gate coupled to receive said second wake-up signal and said selected-power-supply-value, and to generate a second control signal; and
a second AND gate coupled to receive said second wake-up signal and said fifth-inverter-output, and to generate a third control signal.

18. The system of claim 17, wherein said line card further comprises:
a first switch coupled between a power supply node of said circuit and said first power supply, wherein said first switch is operable to be closed or open based on a logic value of said second control signal; and
a second switch coupled between said power supply node of said circuit and said second power supply, wherein said second switch is operable to be closed or open based on a logic value of said third control signal.

19. The system of claim 13, wherein said first selection and said second selection comprise whether a manufacturer of said IC or a user of said IC specifies a desired one of said plurality of unequal power supplies to operate said circuit.

20. The system of claim 13, wherein said OTP memory comprises a third bit, which upon being programmed to said programmed value at a fourth time instance following said third time instance further reverts back from said first selection to said second selection.
